(19) United States
(12) Patent Application Publication
(10) Pub. No.: US 2016/0049429 A1
(43) Pub. Date: Feb. 18, 2016

(54) GLOBAL SHUTTER IMAGE SENSOR, AND IMAGE PROCESSING SYSTEM HAVING THE SAME

(71) Applicant: SAMSUNG ELECTRONICS CO., LTD., Suwon-si (KR)

(72) Inventors: Jun Suk LEE, Seoul (KR); Young Chan KIM, Seongnam-si (KR); Jung Chak AHN, Yongin-si (KR); Young Woo JUNG, Yongin-si (KR)

(21) Appl. No.: 14/819,715

(22) Filed: Aug. 6, 2015

(30) Foreign Application Priority Data
Aug. 18, 2014 (KR) 10-2014-0106726

(51) Int. Cl. H01L 27/146

(52) U.S. Cl. CPC H01L 27/1461; H01L 27/14643; H01L 27/14612

(57) ABSTRACT

A global shutter image sensor according to an exemplary embodiment of the present inventive concepts includes a semiconductor substrate including a first surface and a second surface, a photo-electric conversion region formed in the semiconductor substrate, a storage diode formed in a vicinity of the photo-electric conversion region in the semiconductor substrate, a drain region formed above the photo-electric conversion region in the semiconductor substrate, a floating diffusion region formed above the storage diode in the semiconductor substrate, an overflow gate transferring first charges from the photo-electric conversion region to the drain region, a storage gate transferring second charges from the photo-electric conversion region to the storage diode, and a transfer gate transferring the second charges from the storage diode to the floating diffusion region. The overflow gate, the photo-electric conversion region, the storage gate, the storage diode, the transfer gate, and the floating diffusion region are formed in a row.

### CROSS-REFERENCE TO RELATED APPLICATION

Korean Patent Application No. 10-2014-0106726, filed on Aug. 18, 2014, and entitled “Global Shutter Image Sensor, and Image Processing System Having The Same,” is incorporated by reference herein in its entirety.

### BACKGROUND

1. Field

One or more embodiments described herein relate to a global shutter image sensor and an image processing system having a global shutter image sensor.

2. Description of the Related Art

Image sensors are used in a wide range of applications. Examples include digital cameras, mobile phones, home appliances, endoscopes, and satellite telescopes. Some image sensors are implemented using complementary metal-oxide semiconductor (CMOS) technology. In these sensors, the number of MOS transistors equal the number of pixels. The transistors are used to convert optical images to electrical signals.

A number of methods may be used to drive the pixel circuits of a CMOS image sensor. Examples include a rolling shutter method and a global shutter method. In the rolling shutter method, signals are photo-electrically converted by photo elements in each row in one frame. The signals are transferred to one or more floating diffusion nodes in each row that is sequentially selected, and an image signal of a corresponding pixel is output.

In the global shutter method, all signals are photo-electrically converted by all photo elements in one frame. The signals are transferred to one or more floating diffusion nodes at once. Then, an image signal of a corresponding pixel in a row that is sequentially selected is output.

However, it is difficult for an image sensor that operates based on the global shutter method to include a plurality of transistors for a given pixel pitch. As a result, charges generated by a photo-electric conversion element cannot be moved in one direction, and the charges are sometimes isolated in a pixel when a moving route is changed.

### SUMMARY

In accordance with one or more embodiments, a global shutter image sensor includes a semiconductor substrate including a first surface and a second surface; a photo-electric conversion region in the semiconductor substrate; a storage diode in the semiconductor substrate adjacent the photo-electric conversion region; a drain region adjacent the photo-electric conversion region in the semiconductor substrate; a floating diffusion region adjacent the storage diode in the semiconductor substrate; an overflow gate to transfer first charges from the photo-electric conversion region to the drain region; a storage gate to transfer second charges from the photo-electric conversion region to the storage diode; and a transfer gate to transfer the second charges from the storage diode to the floating diffusion region, wherein the overflow gate, the photo-electric conversion region, the storage gate, the storage diode, the transfer gate, and the floating diffusion region are in a same row.

The photo-electric conversion region may generate the first charges and the second charges in response to incident light received through the first surface or the second surface. The transfer gate may vertically extend from the first surface toward the storage diode. The overflow gate may vertically extend from the first surface towards the photo-electric conversion region. The storage gate may vertically extend from the first surface towards the photo-electric conversion region or the storage diode.

The image sensor may include a reset transistor adjacent the photo-electric conversion region and one side of the overflow gate, the reset transistor to reset the floating diffusion region; and a source follower adjacent the photo-electric conversion region and another side of the overflow gate, the source follower connected to the floating diffusion region. The photo-electric conversion region may be at a first depth from the first surface and the storage diode may be at a second depth from the first surface.

The image sensor may include an isolation region which electrically isolates the photo-electric conversion region from the storage diode, wherein the isolation region includes a deep trench isolation (DTI) region. The isolation region may vertically extend from the first surface or the second surface.

In accordance with one or more other embodiments, a global shutter image sensor includes a semiconductor substrate including a first surface and a second surface; a first pixel; a second pixel; and a third pixel, wherein: a first overflow gate. a first photo-electric conversion region, and a first storage gate of the second pixel are between a first signal processing region of the first pixel, a second overflow gate, a second photo-electric conversion region, and a second storage gate of the third pixel are between a second signal processing region of the second pixel, a first storage diode, a first transfer gate, and a first floating diffusion region of the second pixel are between the first storage gate and the second photo-electric conversion region, and the first overflow gate, the first photo-electric conversion region, the first storage diode, and the first floating diffusion region are arranged in a same row.

The second signal processing region may include a first source follower, a first selection transistor, and a first reset transistor. The first overflow gate, the first storage gate, and the first transfer gate may be formed on the first surface, and the first photo-electric conversion region, the first storage diode, and the first floating diffusion region may be in the semiconductor substrate.

The first photo-electric conversion region may generate charges in response to incident light received through the first surface or the second surface, the first storage diode may be adjacent the first photo-electric conversion region, and the first floating diffusion region may be adjacent the first storage diode. The first transfer gate may vertically extend from the first surface to the first storage diode. The first overflow gate may vertically extend from the first surface to the first photo-electric conversion region.

In accordance with one or more other embodiments, a global shutter image sensor includes a photo-electric converter; a storage diode coupled to the photo-electric converter; a floating diffusion region coupled to the storage diode; and a gate to transfer charges from the photo-electric converter to a drain region to prevent overflow into the storage diode, wherein the gate, the photo-electric converter, the storage diode, and the floating diffusion region are in a same row. The photo-electric converter may be at a first depth in a substrate, and the storage diode may be at a second depth in the substrate. The first depth may be different from the second depth. The gate may extend into a region of the photo-electric converter. The gate may be spaced from the photoelectric converter.

### BRIEF DESCRIPTION OF THE DRAWINGS

Features will become apparent to those of skill in the art by describing in detail exemplary embodiments with reference to the attached drawings in which:

FIG. 1 illustrates an embodiment of an image processing system;

FIG. 2 illustrates an embodiment of a pixel array in FIG. 1;

FIG. 3 illustrates an embodiment of a unit pixel in FIG. 1;

FIGS. 4A and 4B illustrate embodiments of the unit pixel;

FIGS. 5A and 5B illustrate additional embodiments of the unit pixel;

FIG. 6 illustrates an embodiment of a pixel group in FIG. 1;

FIGS. 7A and 7B illustrate embodiments of a unit pixel in FIG. 6;

FIG. 8 illustrates an embodiment of a pixel circuit in FIG. 6;

FIG. 9 illustrates potentials and control signals for the pixel circuit;

FIG. 10 illustrates another embodiment of an image processing system; and

FIG. 11 illustrates another embodiment of an image processing system.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “and/or” includes any and all combinations of one or more of the associated listed items and may be abbreviated as “/”.

It will be understood that, although the terms first, second. etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

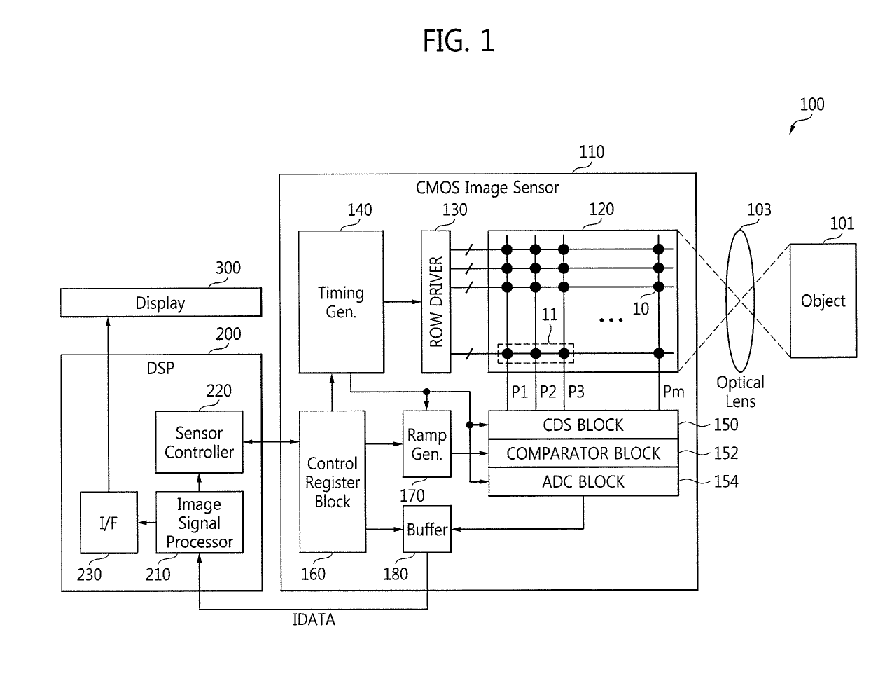

FIG. 1 illustrates an embodiment of an image processing system 100 which, for example, may be embodied in a portable electronic device. Examples of the portable electronic device include a laptop computer, a mobile phone, a smart phone, a tablet PC, a personal digital assistant (PDA), an enterprise digital assistant (EDA), a digital still camera, a digital video camera, a portable multimedia player (PMP), a mobile internet device (MID), a wearable computer, an internet of things (IoT) device, an an internet of everything (IoE) device.

The image processing system 100 includes an optical lens 103, a CMOS image sensor 110, a digital signal processor (DSP) 200, and a display 300.

The CMOS image sensor 110 generates image data IDATA for a object 101 input (or captured) through the optical lens 103. The CMOS image sensor 110 includes a pixel (or an active pixel sensor (APS)) array 120, a row driver 130, a timing generator 140, a correlated double sampling (CDS) block 150, a comparator block 152, an analog-to-digital conversion (ADC) block 154, a control register block 160, a ramp signal generator 170, and a buffer 180. The CMOS image sensor 110 may perform a global shutter operation.

The pixel array 120 includes a plurality of pixels 10 arranged in a matrix form. Each of the pixels 10 has a structure which may increase the amount of charges stored in a floating diffusion node without increasing an operational voltage and capacitance of the floating diffusion node (or floating diffusion region).

The row driver 130 transfers a plurality of control signals for controlling the operation of each of the pixels 10 to the pixel array 120 according to control by the timing generator 140. For example, the timing generator 140 controls the operation of the row driver 130, the CDS block 150, the ADC block 154, and the ramp signal generator 170 under control of the control register block 160.

The CDS block 150 performs correlated double sampling on each pixel signal P1 to Pm (m is a natural number of two or more) output from each of a plurality of column lines in the pixel array 120. The comparator block 152 compares each of a plurality of correlated double sampled pixel signals from the CDS block 150 with a ramp signal output from the ramp signal generator 170, and outputs a plurality of comparison signals according to a result of the comparison.

The ADC block 154 converts the comparison signals from the comparator block 152 to digital signals for output to the buffer 180. The control register block 160 controls the operation of the timing generator 140, the ramp signal generator 170, and the buffer 180 under control of the control register DSP 200. The buffer 180 transfers image data IDATA corresponding to the digital signals from the ADC block 154 to the DSP 200.

The DSP 200 includes an image signal processor 210, a sensor controller 220, and an interface 230. The image signal processor 210 controls the sensor controller 220 for controlling the control register block 160 and also controls the interface 210. In exemplary embodiment, the CMOS image sensor 110 and the DSP 200 are embodied in a chip and, for example, may be embodied in one package, e.g., a multi-chip package. In another exemplary embodiment, the CMOS image sensor 110 and the image signal processor 210 are embodied in a chip and, for example, may be embodied in one package, e.g., a multi-chip package. In another exemplary embodiment, the CMOS image sensor 110 and the image signal processor 210 may be embodied in one chip.

The image signal processor 210 processes the image data IDATA from the buffer 180 and transfers processed image data to the interface 230. The sensor controller 220 generates various control signals for controlling the control register block 160 under control of the image signal processor 210. The interface 230 transfers the image data processed by the image signal processor 210 to the display 300.

The display 300 displays the image data output from the interface 230. The display 300 may be, for example, a thin film transistor-liquid crystal display (TFT-LCD), a light emitting diode (LED) display, an organic LED (OLED) display, or an active-matrix OLED (AMOLED) display.

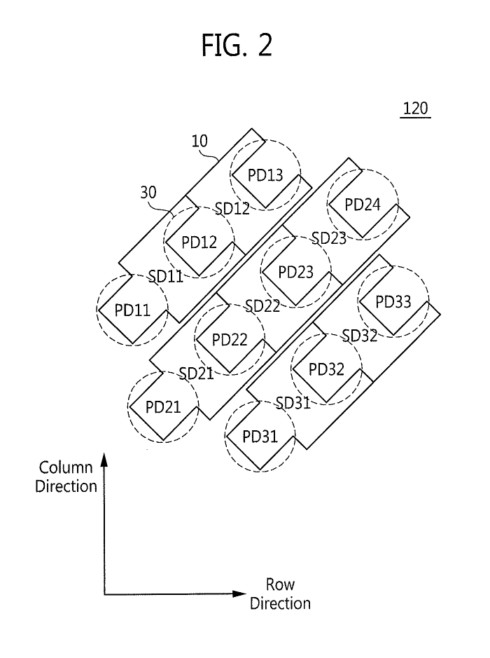

FIG. 2 illustrates a plan view of one embodiment of the pixel array 120 in FIG. 1. Referring to FIGS. 1 and 2, the pixel array 120 includes a plurality of pixels which generate photo charges according to light incident through the optical lens 103, and generates pixel signals corresponding to the photo charges. The pixels may be arranged in a matrix form with n (n is an integer of two or more) rows and m (m is an integer of two or more) columns. The pixels may be octagonal-type pixels or pixels of other type.

Each pixel may include a photo-electric conversion region, and a storage diode for storing photo charges output from the photo-electric conversion region. Each pixel outputs a corresponding pixel signal to a column line. For example, a photo-electric conversion element in the photo-electric conversion region may be a photo diode, a photo transistor, a photo gate, or a pinned photo diode. For convenience of description, the structure and operation of unit pixel 10 is described, with the understanding that other pixels in the array may have the same or similar structure and function.

The unit pixel 10 includes a photo-electric conversion region PD12 and a storage diode SD12. In one exemplary embodiment, the photo-electric conversion region PD12 and the storage diode SD12 in one unit pixel 10 may be arranged at an angle (e.g., an oblique angle) with respect to a row direction of the pixel array 120. A micro-lens 30 may included in or coupled to an upper portion of the photo-electric conversion region PD12. For example, in an arrangement of the pixel array 120, the storage diode SD22 may be surrounded by four photo-electric conversion regions PD12, PD22, PD23, and PD32. In this case, the micro-lens 30 is on an upper portion of each of the photo-electric conversion regions PD12, PD22, PD23, and PD32, and the micro-lens 30 is not on an upper portion of the storage diode SD22.

In FIG. 2, the photo-electric conversion region PD12 and the storage diode region SD12 are oriented at a given angle with respect to the row direction of the pixel array 120. This angle may be different in another embodiment.

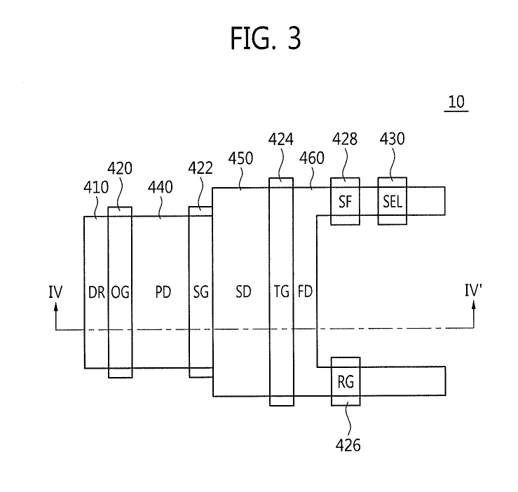

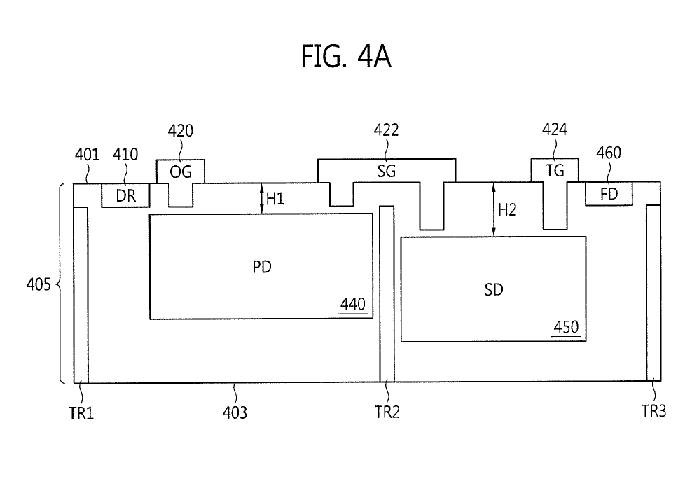

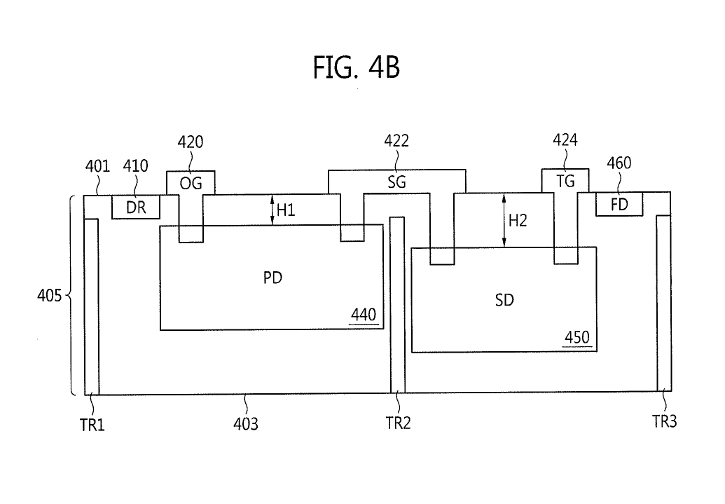

FIG. 3 illustrates a plan view of an embodiment of the unit pixel 10 in FIG. 1, and FIGS. 4A and 4B are cross-sectional views of different embodiments of the unit pixel 10 along line IV-IV′ in FIG. 3. In FIG. 3, features 410 to 460 in the unit pixel 10 are projected onto the same plane for convenience of description. However, features 410 to 460 may not all be coplanar in another embodiment.

Referring to FIGS. 1 to 4B, a semiconductor substrate 405 includes a first surface 401 opposing a second surface 403. In the semiconductor substrate 405, a drain region 410, a photo-electric conversion region 440, a storage diode 450, and a floating diffusion region 460 may be formed.

The drain region 410 is above the photo-electric conversion region 440 in the semiconductor substrate 405, the storage diode 450 is located in the vicinity of the photo-electric conversion region 440, and the floating diffusion region 460 is above the storage diode 450 in the semiconductor substrate 405. According to an exemplary embodiment, the photo-electric conversion region 440 may be formed at a first depth H1 from the first surface 401, and the storage diode 450 may be formed at a second depth H2 from the first surface 401. According to an exemplary embodiment, the first depth H1 may be equal to or different from the second depth H2.

The photo-electric conversion region 440 generates first charges in response to incident light received through one of the first surface 401 or the second surface 403. The first charges may include second charges transferred to the drain region 410 and third charges transferred to the storage diode 450. According to exemplary embodiments, the first charges may correspond to the second charges or the third charges.

An overflow gate 420 is vertically formed from the first surface 401 to the photo-electric conversion region 440, to transfer the second charges from the photo-electric conversion region 440 to the drain region 410. The storage gate 422 is vertically formed from the first surface 401 to the photo-electric conversion region 440 and/or the storage diode 450, to transfer the third charges from the photo-electric conversion region 440 to the storage diode 450.

A transfer gate 424 is vertically formed from the first surface 401 to the storage diode 450, to transfer the third charges from the storage diode 450 to the floating diffusion region 460. A reset transistor 426, in FIG. 3, may be connected between a node supplying an operational voltage and the floating diffusion region 460, and may reset the floating diffusion region 460. A source follower 428 operates in response to a voltage corresponding to the third charges transferred to the floating diffusion region 460. A selection transistor 430 transfers signals from the source follower 428 to a column line.

Referring to FIG. 3, the overflow gate 420, the photo-electric conversion region 440, the storage gate 422, the storage diode 450, the transfer gate 424, and the floating diffusion region 460 may be in a row. According to an exemplary embodiment, the unit pixel 10 may include first isolation regions TR1 and TR3 which electrically isolate the unit pixel 10 from adjacent pixels, and a second isolation region TR2 which electrically isolates the photo-electric conversion region 440 from the storage diode 450. The first isolation regions TR1 and TR3 and the second isolation region TR2 may be deep trench isolation (DTI) regions.

The first isolation regions TR1 and TR3 and the second isolation region TR2 may be formed, for example, using a back trench process or a front trench process. Thus, the first isolation regions TR1 and TR3 and the second isolation region TR2 may be vertically formed from one of the first surface 401 and the second surface 403.

According to an exemplary embodiment, the unit pixel 10 may include a shallow trench isolation (STI) region which electrically isolates a plurality of transistors from one another in the unit pixel 10.

Referring to FIGS. 4A and 4B, the CMOS image sensor 110 may operate based on a front side illumination (FSI) method. For example, incident light may be incident through the first surface 401. The embodiments of FIGS. 4A and 4B may different in respect to the structures of the overflow gate 420, the storage gate 422, and the transfer gate 424. In FIG. 4A, the overflow gate 420, the storage gate 422, and the transfer gate 424 do not vertically extend into the photo-electric conversion region 440 and the storage diode 450. In FIG. 4B, the overflow gate 420, the storage gate 422, and the transfer gate 424 are vertically extend into the photo-electric conversion region 440 and the storage diode 450. In another embodiment, the overflow gate 420 may vertically extend into the photo-electric conversion region 440 and/or the storage gate 422 and the transfer gate 424 may vertically extend into the storage diode 450.

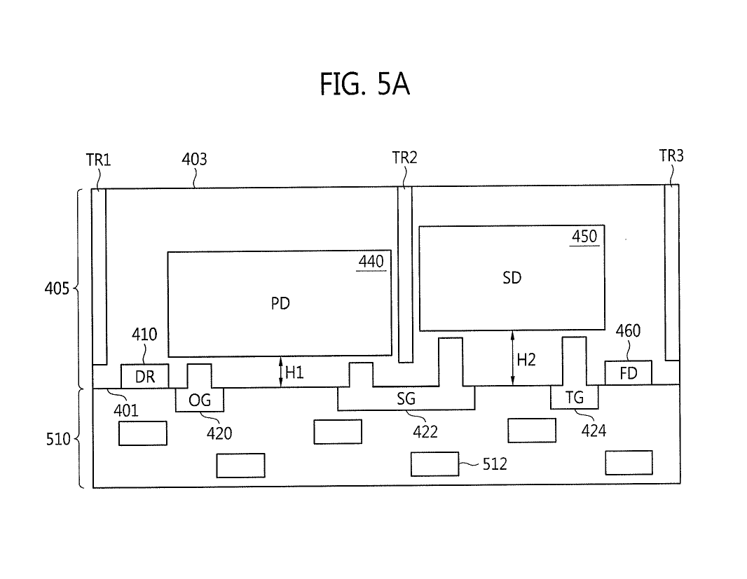

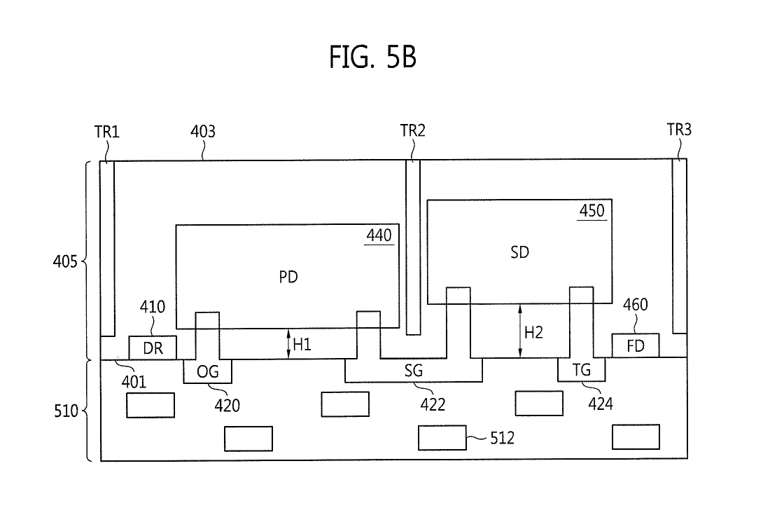

FIGS. 5A and 5B illustrate cross-sectional views of additional embodiments of the 10 unit pixel taken along line IV-IV′ in FIG. 3. Referring to FIGS. 5A and 5B, the CMOS image sensor 110 may be a CMOS image sensor that operates according to a backside illumination (BSI) method. For example, incident light may be incident through the second surface 403.

Referring to FIGS. 1 to 5B, the semiconductor substrate 405 includes the first surface 401 and the second surface 403, and the drain region 410, the photo-electric conversion region 440, the storage diode 450, and the floating diffusion region 460 are formed in the semiconductor substrate 405. A wiring layer 510 may be formed under the first surface 401 and may include conductive lines 512 or metal.

Referring to FIG. 5A, the overflow gate 420, the storage gate 422, and the transfer gate 424 do not vertically extend into the photo-electric conversion region 440 and/or the storage diode 450 from the first surface 401.

Referring to FIG. 5B, the overflow gate 420, the storage gate 422, and/or the transfer gate 424 vertically extend into the photo-electric conversion region 440 and/or the storage diode 450 from the first surface 401. In another embodiment, the overflow gate 420 may extend into the photo-electric conversion region 440 and/or the storage gate 422 and the transfer gate may extend into the storage diode 450.

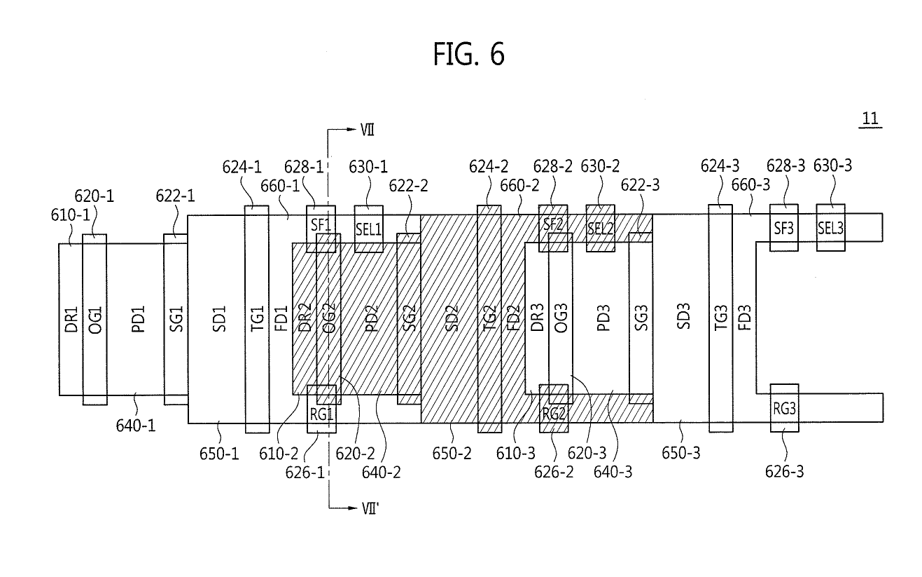

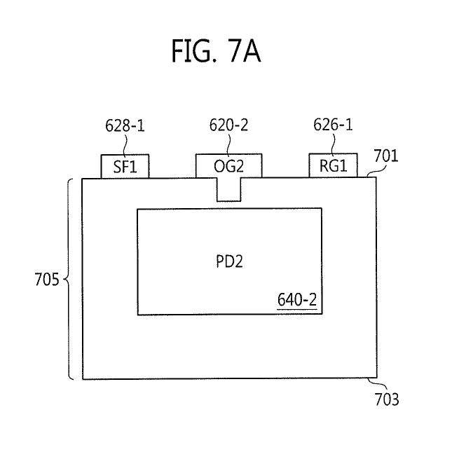

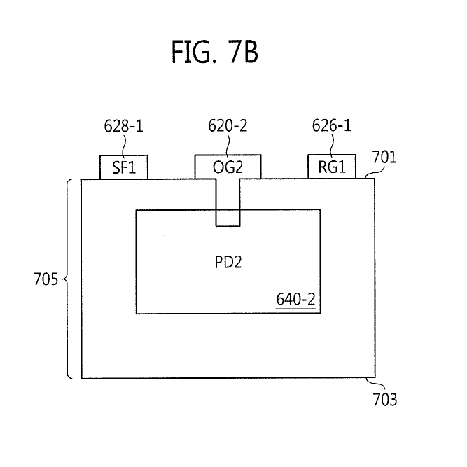

FIG. 6 illustrates a plan view of an embodiment of a pixel group 11 in FIG. 1, and FIGS. 7A and 7B are cross-sectional views of different embodiments of a unit pixel taken along line VII-VII′ in FIG. 6. For convenience of description, in FIG. 6, each of the features 610-1 to 660-3 in the pixel group 11 include three pixels projected onto the same plane. In another embodiment, features 610-1 to 660-3 may not all be coplanar.

Referring to FIG. 6, the pixel group 11 includes three pixels continuously disposed among the pixels in the pixel array 120 of FIG. 1. The structure and operation of the three pixels may be substantially the same as or similar to the structure and operation of the pixel in FIG. 3. Referring to FIGS. 1 and 6, the pixel group 11 includes a first pixel, a second pixel, and a third pixel. The semiconductor substrate 705 of each pixel of the pixel group 11 includes the first surface 701 and the second surface 703 (see FIGS. 7A and 7B), and the drain region 610-1, 610-2, or 610-3, the photo-electric conversion region 640-1, 640-2, or 640-3, the storage diode 650-1, 650-2, or 650-3, and the floating diffusion region 660-1, 660-2, or 660-3 may be formed in the semiconductor substrate 705.

Referring to FIG. 6, the first pixel includes a first drain region 610-1, a first overflow gate 620-1, a first photo-electric conversion region 640-1, a first storage gate 622-1, a first storage diode 650-1, a first transfer gate 624-1, a first floating diffusion region 660-1, a first reset gate 626-1, a first source follower 628-1, and a first selection transistor 630-1.

The second pixel adjacent to the first pixel includes a second drain region 610-2, a second overflow gate 620-2, a second photo-electric conversion region 640-2, a second storage gate 622-2, a second storage diode 650-2, a second transfer gate 624-2, a second floating diffusion region 660-2, a second reset gate 626-2, a second source follower 628-2, and a second selection transistor 630-2.

The third pixel adjacent to the second pixel includes a third drain region 610-3, a third overflow gate 620-3, a third photo-electric conversion region 640-3, a third storage gate 622-3, a third storage diode 650-3, a third transfer gate 624-3, a third floating diffusion region 660-3, a third reset gate 626-3, a third source follower 628-3, and a third selection transistor 630-3. The structure of the second pixel is illustrated in FIGS. 7A and 7B, with the understanding that the first and third pixels may have substantially the same or a similar structure.

The second overflow gate 620-2, the second photo-electric conversion region 640-2, and the second storage gate 622-2 of the second pixel are between a first signal processing region of the first pixel. The first signal processing region includes the first reset gate 626-1, the first source follower 628-1, and the first selection transistor 630-1 of the first pixel.

The third overflow gate 620-3, the third photo-electric conversion region 640-3, and the third storage gate 622-3 of the third pixel are between a second signal processing region of the second pixel. The second signal processing region includes the second reset gate 626-2. the second source follower 628-2, and the second selection transistor 630-2 of the second pixel.

The second storage diode 650-2, the second transfer gate 624-2, and the second floating diffusion region 660-2 of the second pixel are between the second storage gate 622-2 of the second pixel and the third photo-electric conversion region 640-3 of the third pixel. The second overflow gate 620-2, the second photo-electric conversion region 640-2, the second storage diode 650-2, and the second floating diffusion region 660-2 of the second pixel may be arranged in a row.

Referring to FIGS. 1 and 6, the second photo-electric conversion region 640-2 may generate first charges in response to incident light received through one of the first surface 401 and the second surface 403. The first charges may include second charges transferred to the second drain region 610-2 and third charges transferred to the second storage diode 650-2.

During a reset operation, the second overflow gate 620-2 may transfer the second charges from the second photo-electric conversion region 640-2 to the second drain region 610-2.

During a transfer operation, the second storage gate 622-2 may transfer the third charges from the second photo-electric conversion region 640-2 to the second storage diode 650-2. During the transfer operation, the second transfer gate 624-2 may transfer the third charges from the second storage diode 650-2 to the second floating diffusion region 660-2.

The second reset transistor 626-2 is connected between a node supplying an operational voltage and the second floating diffusion region 660-2. The second reset transistor 626-2 operates to reset the second floating diffusion region 660-2. The second source follower 628-2 may operate in response to the third charges transferred to the second floating diffusion region 660-2. The second selection transistor 630-2 may transfer signals output from the second source follower 628-2 to a column line.

Referring to FIGS. 1 to 7B, a semiconductor substrate 705 includes a first surface 701 and a second surface 703. The first reset transistor 626-1 and the first source follower 628-1 of the first pixel may be on the first surface 701. The second photo-electric conversion region 640-2 may be formed in the semiconductor substrate 705.

The first reset transistor 626-1 of the first pixel may be above the second photo-electric conversion region 640-2 and at one side of the second overflow gate 620-2. The first reset transistor 626-1 may reset the second floating diffusion region 660-2. The first source follower 628-1 of the first pixel may be above the second photo-electric conversion region 640-2 and at the other side of the second overflow gate 620-2, and may be connected to the second floating diffusion region 660-2.

Except for the structure of the second overflow gate 620-2, the embodiments of FIGS. 7A and 7B may be the same or similar to one another. In the embodiment of FIG. 7A, the second overflow gate 620-2 does not vertically extend into the second photo-electric conversion region 640-2. In the embodiment of FIG. 7B, the second overflow gate 620-2 vertically extends into the second photo-electric conversion region 640-2.

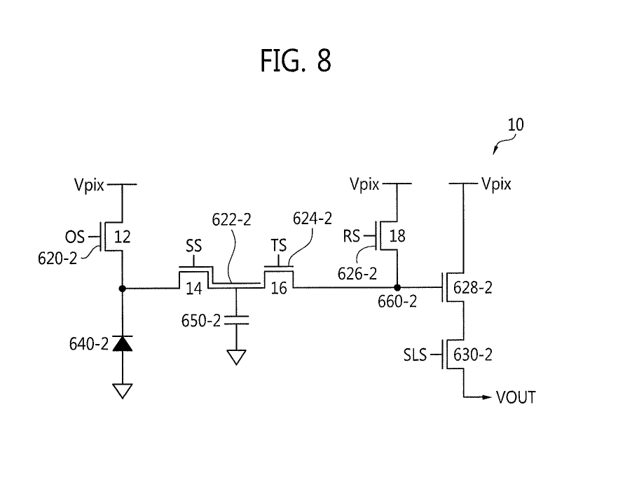

FIG. 8 illustrates an embodiment of a pixel circuit of the second pixel in FIG. 6. Referring to FIGS. 6 and 8, the pixel circuit of unit pixel 10 is to perform a global shutter operation and includes the photo-electric conversion region 640-2, an overflow transistor 12, a storage transistor 14, a transfer transistor 16, a reset transistor 18, the source follower 628-2, and the selection transistor 630-2.

The photo-electric conversion region 640-2 accumulates or collects charges in response to incident light.

The overflow transistor 12 is connected between a first node supplying an operational voltage Vpix and the photo-electric conversion region 640-2. The overflow transistor 12 includes the overflow gate 620-2. The overflow gate 620-2 is used to prevent an overflow of charges generated by the photo-electric conversion region 640-2. The overflow transistor 12 is turned on or off in response to an overflow gate signal OS.

For example, when the intensity of light incident on the unit pixel 10 is large, or when attempting to capture an image which includes a bright light source such as the sun, a light bulb, or the like (e.g., a high illumination source), the overflow transistor 12 is used to prevent an overflow of charges from being transferred from the photo-electric conversion region 640-2 to the storage diode 650-2.

The storage transistor 14 is connected between the photo-electric conversion region 640-2 and the storage diode 650-2. The charges transferred from the photo-electric conversion region 640-2 pass through the storage transistor 14 and are stored in the storage diode 650-2. The storage transistor 14 is turned on or off in response to a storage transistor control signal SS supplied to the storage gate 622-2.

The transfer transistor 16 is connected between the storage transistor 14 and the floating diffusion node 660-2. The charges stored in the storage diode 650-2 pass through the transfer transistor 16 for storage or accumulation in the floating diffusion node 660-2. The transfer transistor 16 is turned on or off in response to the transfer control signal TS supplied to the transfer gate 624-2.

The reset transistor 18 may be connected between the first node supplying an operational voltage Vpix and the floating diffusion node 660-2. The reset transistor 18 controls the transfer of charges (e.g., electrons) of the floating diffusion node 660-2 to the first node in response to a reset control signal RS supplied to the reset gate 626-2. The source follower 628-2 is connected between the first node supplying an operational voltage Vpix and the selection transistor 630-2. The source follower 628-2 operates based on a voltage determined according to the charges of the floating diffusion node 660-2. The selection transistor 630-2 may output an output signal (e.g., an analog pixel signal: VOUT) of the source follower 628-2 to a column line in response to a selection signal SLS.

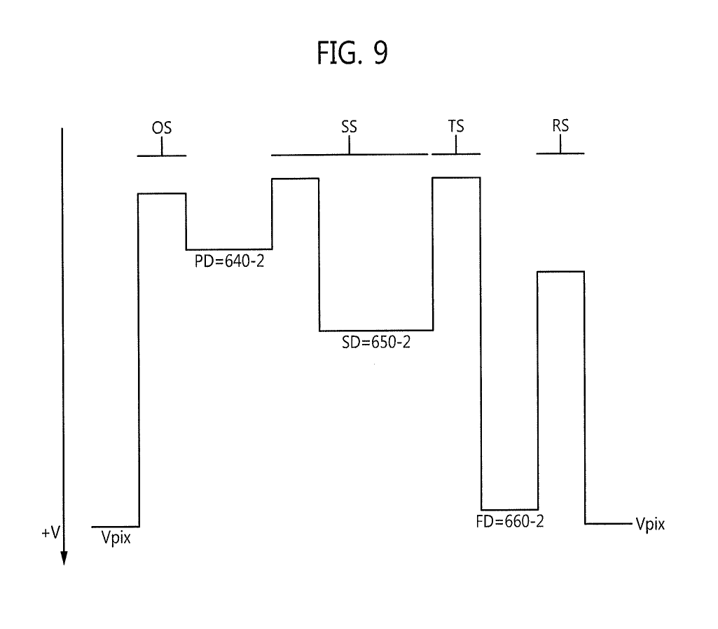

FIG. 9 is a potential diagram of control signals in FIG. 8. For convenience of description, it is assumed that each of the transistors 12, 14, 16, 18, 628-2, and 630-2 in FIG. 8 is an NMOS transistor, and that each of the transistors 12, 14, 16, 18, 628-2, and 630-2 is turned on in response to each of control signals OS, SS, TS, RS, and SLS having a high level.

Referring to FIGS. 8 and 9, the photo-electric conversion region 640-2 generates charges in response to incident light. When an overflow gate signal OS having a high level is supplied to the overflow gate 620-2, the charges stored in the photo-electric conversion region 640-2 are discharged to the first node supplying an operational voltage Vpix through the overflow transistor 12.

When a storage transistor control signal SS having a high level is supplied to the storage gate 622-2, the charges stored in the photo-electric conversion region 640-2 are stored in the storage diode 650-2 through the storage transistor 14. When a transfer gate signal TS having a high level is supplied to the transfer gate 16, charges are transferred from the storage diode 650-2 to the floating diffusion region 660-2.

When a reset signal RS having a high level is supplied to the reset gate 626-2, the charges transferred to the floating diffusion node 660-2 are transferred to the first node supplying an operational voltage Vpix. Accordingly, the floating diffusion region 660-2 is reset.

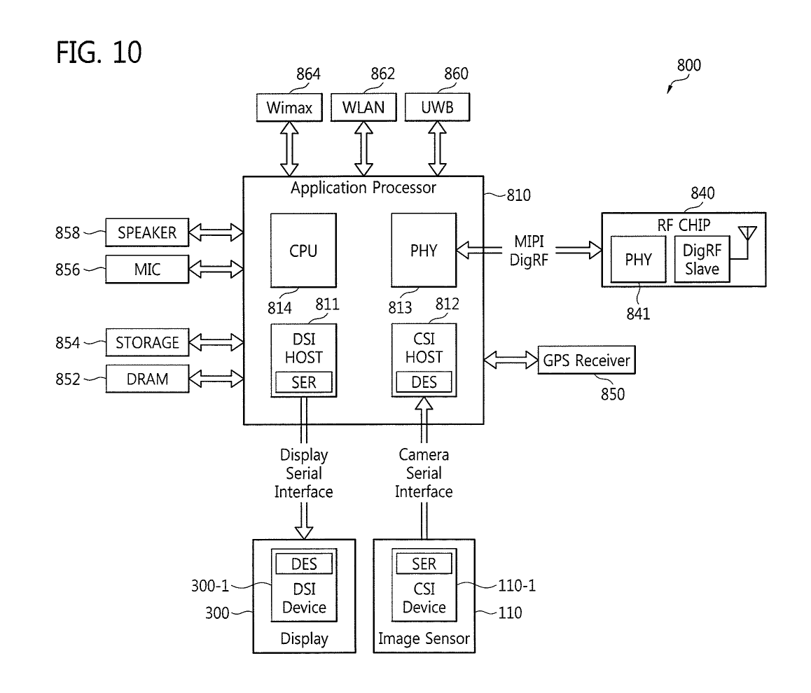

FIG. 10 illustrates an embodiment of an image processing system 800, which, for example, may include the pixel array 120 in FIG. 1. Referring to FIGS. 1 to 10, the image processing system 800 may use or support, for example, a mobile industry processor interface (MIPI®). The image processing system 800 may be embodied, for example, in a laptop computer, a mobile phone, a smart phone, a tablet PC, a personal digital assistant (PDA), an enterprise digital assistant (EDA), a digital still camera, a digital video camera, a portable media player (PMP), a mobile internet device (MID), a wearable computer, an internet of things (IoT) device, or an internet of everything (IoE) device.

The image processing system 800 includes an application processor (AP) 810, the CMOS image sensor 110, and the display 300.

A camera serial interface (CSI) host 812 embodied in the AP 810 can perform a serial communication with a CSI device 110-1 of the CMOS image sensor 110 through a CSI. According to an exemplary embodiment, the CSI host 812 may include a de-serializer (DES), and the CSI device 110-1 may include a serializer (SER). The CMOS image sensor 110 may correspond to any of the embodiments in FIGS. 1 to 9.

A display serial interface (DSI) host 811 embodied in the AP 810 may perform a serial communication with a DSI device 300-1 of the display 300 through a DSI. According to an exemplary embodiment, the DSI host 811 may include a sirializer (SER), and the DSI device 300-1 may include a de-serializer (DES). For example, image data (for example, IDATA of FIG. 1) output from the CMOS image sensor 110 may be transferred to the AP 810 through the CSI. The AP 810 may process the image data (for example, IDATA of FIG. 1), and transfer processed image data to the display 300 through the DSI.

The image processing system 800 may further include a RF chip 840 which can communicate with the AP 810. A physical layer (PHY) of the image processing system 800 and a physical layer (PHY) of the RF chip 840 may transmit or receive data to or from each other according to MIPI DigRF. The CPU 814 may control an operation of each of the DSI host 811, the CSI host 812, and the PHY 813, and may include one or more cores.

The AP 810 may be embodied in an integrated circuit or a system on chip (SoC), and may correspond to a processor or a host for controlling operation of the CMOS image sensor 110.

The CMOS image sensor 110 may include a GPS receiver 850, a volatile memory 852 such as a dynamic random access memory (DRAM), a data storage device 854 embodied in a non-volatile memory such as a flash-based memory, a microphone 856, or a speaker 858. The data storage device 854 may be embodied in an external memory which is attachable and detachable from the AP 810. In addition, the data storage device 854 may be embodied in a universal flash storage (UFS), a multimedia card (MMC), an embedded MMC (eMMC), an USB flash drive, and a memory card.

The image processing system 800 may communicate with an external device using at least one communication protocol (or communication standard), e.g., a ultra-wideband (UWB) 860, a wireless LAN (WLAN) 862, a worldwide interoperability for microwave access (WiMAX) 864, or a long term evolution (LTETM: not shown).

According to an exemplary embodiment, the image processing system 800 may include at least one of an NFC module, a WiFi module, or a Bluetooth module.

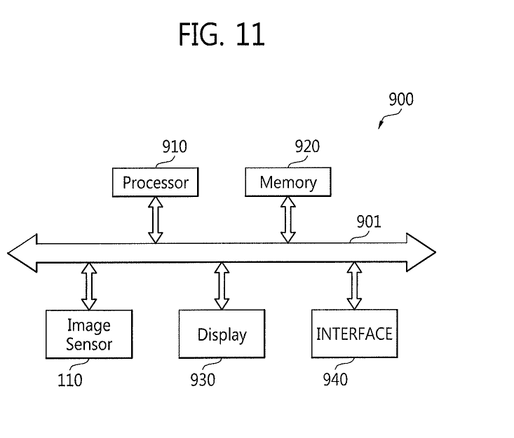

FIG. 11 illustrates another embodiment of an image processing system 900 which includes the CMOS image sensor 110, a processor 910, a memory 920, a display 930, and an interface 940. The processor 910 may control an operation of the CMOS image sensor 110. For example, the processor 910 may generate image data by processing a pixel signal output from the CMOS image sensor 110.

The memory 920 may store a program for controlling an operation of the CMOS image sensor 110 and the image data generated by the processor 910. The processor 910 may execute a program stored in the memory 920. For example, the memory 910 may be embodied in a volatile memory or a non-volatile memory. The display 930 may display the image data output from the processor 910 or the memory 920.

The interface 940 may be embodied in an interface for inputting or outputting image data. According to an exemplary embodiment, the interface 940 may be embodied in a wire interface or a wireless interface.

By way of summation and review, CMOS image sensors are in widespread use today in many consumer and professional applications. Some CMOS image sensors operate using a rolling shutter method. Others operate using a Global Shutter (GS) method, whereby every pixel of the entire pixel array acquires the image during the same time period. This requires an in-pixel memory element that stores the signal after capture by the photodiode.

However, it is difficult to embody an plurality of transistors in an image sensor operating using the global shutter method because of limited pixel pitch. As a result, and charges generated by a photo-electric conversion element may not adequately move in one direction, and the charges may isolate in a pixel when a moving route is changed.

In accordance with one or more of the aforementioned embodiments, a global shutter image sensor reduces or prevents charges from being isolated in a pixel by allowing charges generated by a photo-electric conversion element to be transferred through continuous line in the same direction in the global shutter image sensor. Additionally, or alternatively, the global shutter may improve sensitivity of a pixel of a global shutter image sensor which includes a photo-electric conversion element and a storage diode, and may also increase full-well capacity.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the invention as set forth in the following claims.

What is claimed is:

1. A global shutter image sensor, comprising:
a semiconductor substrate including a first surface and a second surface;
a photo-electric conversion region in the semiconductor substrate;
a storage diode in the semiconductor substrate adjacent the photo-electric conversion region;
a drain region adjacent the photo-electric conversion region in the semiconductor substrate;
a floating diffusion region adjacent the storage diode in the semiconductor substrate;
an overflow gate to transfer first charges from the photo-electric conversion region to the drain region;
a storage gate to transfer second charges from the photo-electric conversion region to the storage diode; and
a transfer gate to transfer the second charges from the storage diode to the floating diffusion region, wherein the overflow gate, the photo-electric conversion region, the storage gate, the storage diode, the transfer gate, and the floating diffusion region are in a same row.

2. The image sensor as claimed in claim 1, wherein the photo-electric conversion region is to generate the first charges and the second charges in response to incident light received through the first surface or the second surface.

3. The image sensor as claimed in claim 1, wherein the transfer gate vertically extends from the first surface toward the storage diode.

4. The image sensor as claimed in claim 1, wherein the overflow gate vertically extends from the first surface towards the photo-electric conversion region.

5. The image sensor as claimed in claim 1, wherein the storage gate vertically extends from the first surface towards the photo-electric conversion region or the storage diode.

6. The image sensor as claimed in claim 1, further comprising:
a reset transistor adjacent the photo-electric conversion region and one side of the overflow gate, the reset transistor to reset the floating diffusion region; and
a source follower adjacent the photo-electric conversion region and another side of the overflow gate, the source follower connected to the floating diffusion region.

7. The image sensor as claimed in claim 1, wherein the photo-electric conversion region is at a first depth from the first surface, and wherein the storage diode at a second depth from the first surface.

8. The image sensor as claimed in claim 1, further comprising:
an isolation region which electrically isolates the photo-electric conversion region from the storage diode, wherein the isolation region includes a deep trench isolation (DTI) region.

9. The image sensor as claimed in claim 8, wherein the isolation region vertically extends from the first surface or the second surface.

10. A global shutter image sensor, comprising:
a semiconductor substrate including a first surface and a second surface;
a first pixel;
a second pixel; and
a third pixel, wherein:
a first overflow gate, a first photo-electric conversion region, and a first storage gate of the second pixel are between a first signal processing region of the first pixel,
a second overflow gate, a second photo-electric conversion region, and a second storage gate of the third pixel are between a second signal processing region of the second pixel,
a first storage diode, a first transfer gate, and a first floating diffusion region of the second pixel are between the first storage gate and the second photo-electric conversion region, and
the first overflow gate, the first photo-electric conversion region, the first storage diode, and the first floating diffusion region are arranged in a same row.

11. The image sensor as claimed in claim 10, wherein the second signal processing region includes a first source follower, a first selection transistor, and a first reset transistor.

12. The image sensor as claimed in claim 10, wherein:
the first overflow gate, the first storage gate, and the first transfer gate are formed on the first surface, and
the first photo-electric conversion region, the first storage diode, and the first floating diffusion region are in the semiconductor substrate.

13. The image sensor as claimed in claim 10, wherein:
the first photo-electric conversion region is to generate charges in response to incident light received through the first surface or the second surface,
the first storage diode is adjacent the first photo-electric conversion region, and
the first floating diffusion region is adjacent the first storage diode.

14. The image sensor as claimed in claim 10, wherein the first transfer gate vertically extends from the first surface to the first storage diode.

15. The image sensor as claimed in claim 10, wherein the first overflow gate vertically extends from the first surface to the first photo-electric conversion region.

16. A global shutter image sensor, comprising:
a photo-electric converter;
a storage diode coupled to the photo-electric converter;
a floating diffusion region coupled to the storage diode; and
a gate to transfer charges from the photo-electric converter to a drain region to prevent overflow into the storage diode, wherein the gate, the photo-electric converter, the storage diode, and the floating diffusion region are in a same row.

17. The image sensor as claimed in claim 16, wherein:
the photo-electric converter is at a first depth in a substrate,
the storage diode is at a second depth in the substrate.

18. The image sensor as claimed in claim 17, wherein the first depth is different from the second depth.

19. The image sensor as claimed in claim 16, wherein the gate extends into a region of the photo-electric converter.

20. The image sensor as claimed in claim 16, wherein the gate is spaced from the photoelectric converter.
